(19) United States
(12) Patent Application Publication
(10) Pub. No.: US 2025/0194004 A1
(43) Pub. Date: Jun. 12, 2025

(54) PRINTED CIRCUIT BOARD

(71) Applicant: SAMSUNG ELECTRO-MECHANICS CO., LTD., Suwon-si (KR)

(72) Inventors: Mi Sun Hwang, Suwon-si (KR); Mi Jeong Jeon, Suwon-si (KR); Tae Hee Yoo, Suwon-si (KR); Young Ook Cho, Suwon-si (KR)

(73) Assignee: SAMSUNG ELECTRO-MECHANICS CO., LTD., Suwon-si (KR)

(21) Appl. No.: 18/797,085

(22) Filed: Aug. 7, 2024

(30) Foreign Application Priority Data
Dec. 7, 2023 (KR) 10-2023-0176390

(51) Int. Cl. H05K 1/03; H05K 1/02; H05K 1/11; H05K 1/18

(52) U.S. Cl. CPC H05K 1/0306; H05K 1/0271; H05K 1/115; H05K 1/185; H05K 2201/0175

(57) ABSTRACT

A printed circuit board includes a glass layer having a cavity, a through-via having a through-portion penetrating the glass layer, and a protrusion portion protruding upwards from an upper surface of the glass layer, an electronic component disposed in the cavity, and a first insulating layer filling at least a portion of the cavity, the first insulating layer covering at least a portion of the electronic component.

### CROSS-REFERENCE TO RELATED APPLICATION(S)

This application claims the benefit of priority to Korean Patent Application No. 10-2023-0176390 filed on Dec. 7, 2023 in the Korean Intellectual Property Office, the disclosure of which is incorporated herein by reference in its entirety.

### TECHNICAL FIELD

The present disclosure relates to a printed circuit board.

### BACKGROUND

Multichip packages including a memory chip such as a high bandwidth memory (HBM) and a processor chip such as a central processing unit (CPU), a graphics processing unit (GPU), an application specific integrated circuit (ASIC), or a field programmable gate array (FPGA) have been used to process data, which has been exponentially increasing due to recent developments in artificial intelligence (AI) technology. Accordingly, there is a demand for a board having a large-area structure, and continuous efforts have been conducted to overcome the issue associated with flatness and warpage control.

### SUMMARY

An aspect of the present disclosure provides a printed circuit board including a glass layer.

Another aspect of the present disclosure provides a printed circuit board having improved warpage properties.

Another aspect of the present disclosure provides a printed circuit board having improved reliability.

According to an aspect of the present disclosure, there is provided a printed circuit board including a glass layer having a cavity, a through-via having a through-portion penetrating the glass layer, and a protrusion portion protruding upwards from an upper surface of the glass layer, an electronic component disposed in the cavity, and a first insulating layer filling at least a portion of the cavity, the first insulating layer covering at least a portion of the electronic component.

According to another aspect of the present disclosure, there is provided a printed circuit board including a glass layer, and a through-via having a through-portion penetrating the glass layer, and a protrusion portion protruding upwards from an upper surface the glass layer. In cross-section, a width of an uppermost side of the through-portion may be substantially equal to a width of a lowermost side of the protrusion portion.

According to example embodiments of the present disclosure, a printed circuit board may include a glass layer.

The printed circuit board may have improved warpage properties.

The printed circuit board may have improved reliability.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example of an electronic device system;

FIG. 2 is a schematic perspective view of an example of an electronic device;

FIGS. 3A and 3B are schematic cross-sectional views of a printed circuit board according to an example;

FIGS. 4A and 4B are schematic cross-sectional views of a printed circuit board according to another example;

FIGS. 5A and 5B are schematic cross-sectional views of a printed circuit board according to another example;

FIGS. 6A to 6K are schematic cross-sectional views of a method of manufacturing a printed circuit board according to an example; and

FIGS. 7A to 7D are schematic cross-sectional views of a portion of a method of manufacturing a printed circuit board according to another example.

### DETAILED DESCRIPTION

Hereinafter, the present disclosure will be described with reference to the accompanying drawings. The shapes and sizes of components in the drawings may be exaggerated or reduced for clearer description.

### Electronic Device

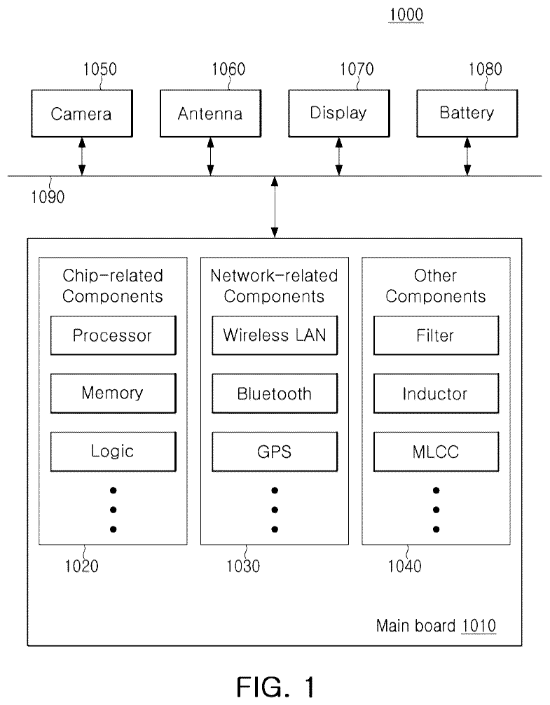

FIG. 1 is a schematic block diagram of an example of an electronic device system.

Referring to FIG. 1, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an m analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+(HSPA+), high speed downlink packet access+(HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

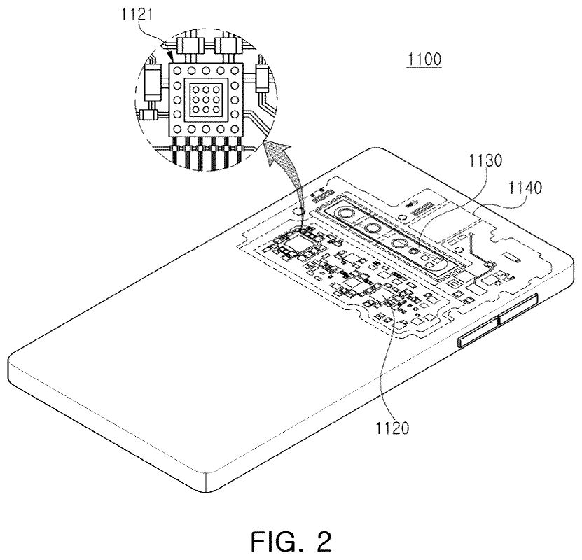

FIG. 2 is a schematic perspective view of an example of an electronic device.

Referring to FIG. 2, an electronic device may be, for example, a smartphone 1100. The motherboard 1110 may be accommodated in the smartphone 1100, and various electronic components 1120 may be physically and/or electrically connected to the motherboard 1110. In addition, other electronic components that may be or may not be physically and/or electrically connected to the motherboard 1110 may be accommodated therein, such as a camera module 1130 and/or a speaker 1140. A portion of the electronic components 1120 may be the chip-related components described above, for example, a component package 1121, but the present disclosure is not limited thereto. The component package 1121 may be in the form of a printed circuit board on which electronic components including active components and/or passive components are surface-mounted. The electronic device is not necessarily limited to the smartphone 1100, and may be other electronic devices, as described above.

### Printed Circuit Board

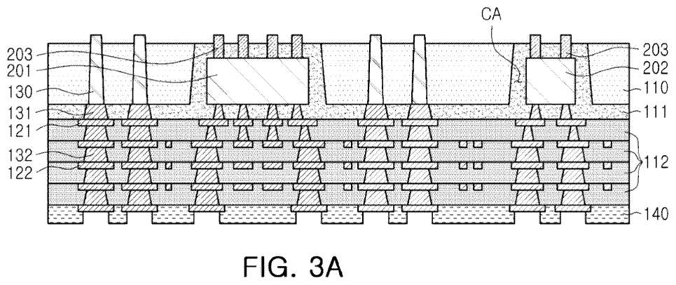

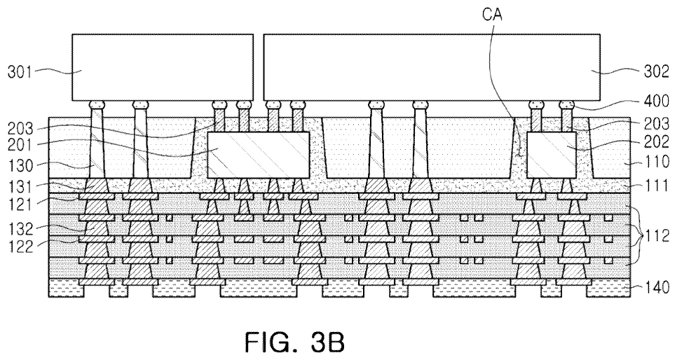

FIGS. 3A and 3B are schematic cross-sectional views of a printed circuit board according to an example.

Referring to FIGS. 3A and 3B, the printed circuit board according to an example may include a glass layer 110 having a cavity CA, a through-via 130 penetrating the glass layer 110, a first insulating layer 111 filling the cavity CA, and electronic components 201 and 202 disposed in the cavity CA. The through-via 130 may penetrate at least a portion of the glass layer 110, and may protrude through a portion of the glass layer 110. That is, the through-via 130 may have a through-portion penetrating the glass layer 110, and a protrusion portion protruding from the glass layer 110. The through-portion and the protrusion portion of the through-via 130 may be integrally formed.

The printed circuit board according to an example may include a glass layer 110, and thus may have excellent flatness. In addition, it may be advantageous for warpage control through a low coefficient of thermal expansion (CTE). In particular, the printed circuit board according to an example may include the glass layer 110 as a core, such that it may be advantageous for warpage control even in an operation of stacking another insulating layer. In addition, the number of layers of the printed circuit board may be reduced and a degree of design freedom may be further increased through a dielectric property of the glass layer 110, such as a feature of glass having a variable property of Dk 2.5 to 11.

The glass layer 110 may be disposed on an outermost side of the printed circuit board. The printed circuit board according to an example may be a coreless-type board in which a first insulating layer 111 and/or a second insulating layer 112 are built up on a lower side of the glass layer 110. The printed circuit board according to an example including the glass layer 110 disposed on the outermost side thereof, such that it may be advantageous for controlling warpage properties even when the coreless-type board is manufactured. In particular, in a large-area coreless-type board, defects caused by warpage may be highly likely to occur. When a fine circuit is implemented or a multilayer board is manufactured, even slight warpage may cause defects in a board. However, in the printed circuit board according to an example, the glass layer 110 may be disposed on the outermost side thereof, and the glass layer 110 may be exposed to an upper side of the printed circuit board, such that it may be advantageous for controlling warpage properties. However, the present disclosure is not limited thereto, and other means may be further included on the completed board to protect the glass layer 110. However, even in this case, the glass layer 110 may be disposed on an uppermost layer, among the build-up layers.

The printed circuit board according to an example may include the glass layer 110 as a component of the board, and the glass layer 110 may form a portion of the build-up layers. The printed circuit board according to an example may be clearly different from a glass interposer having a cavity, manufactured separately from board, and connected through solder or the like. In the printed circuit board according to an example, the glass layer 110 and the first insulating layer 111 may be positioned to be in contact with each other, and a first via layer 131 formed on the glass layer 110 may be in direct contact with the through-via 130. In addition, an arrangement relationship between the glass layer 110, the first insulating layer 111, the first wiring layer 121, and the first via layer 131 of the printed circuit board according to the example will be described below in detail.

The glass layer 110 may include glass, an amorphous solid. Glass may include, for example, pure silicon dioxide (about 100% SiO₂), soda lime glass, borosilicate glass, alumino-silicate glass, or the like. However, the present disclosure is not limited thereto, and an alternative glass material, such as fluorine glass, phosphate glass, chalcogen glass, or the like, may also be used as a material of the glass layer 110. In addition, other additives may be further included to form glass having specific physical properties. The above-described additives may include, for example, magnesium, calcium, manganese, aluminum, lead, boron, iron, chromium, potassium, sulfur and antimony, as well as calcium carbonate (for example, lime) and sodium carbonate (for example, soda), and a carbonate and/or an oxide of the above-described elements and other elements. The glass layer 110 may be a layer, distinct from a layer including a material including a glass fiber (glass cloth and/or glass fabric), for example, copper clad laminate (CCL), prepreg (PPG), or the like, and may be understood as, for example, plate glass.

The glass layer 110 may have a cavity CA. The cavity CA may penetrate upper and lower surfaces of the glass layer 110, and may have an upwardly tapered shape. That is, the cavity CA may have a tapered shape such that a width of an upper surface of the glass layer 110 is narrower than a width of a lower surface of the glass layer 110. Such a configuration may be a result of the cavity CA being formed from a lower side to an upper side of the glass layer 110. The present disclosure is not necessarily limited thereto, and the cavity CA may have a tapered shape such that the width of the lower surface of the glass layer 110 is narrower than the width of the upper surface of the glass layer 110, and a width a central portion of the glass layer 110 may be formed to be narrower than each of the widths of the upper and lower surfaces of the glass layer 110, and thus the central portion of the glass layer 110 may be formed to have a narrowest width. Such a configuration may be a result of forming a cavity CA in the glass layer 110 and then attaching the cavity CA to a carrier to manufacture a board. A first electronic component 201 and/or a second electronic component 202 may be mounted in the cavity CA. The first electronic component 201 and the second electronic component 202 may be disposed on the outermost side of the printed circuit board, and may be connected to other electronic components such as a first semiconductor chip 301 and/or a second semiconductor chip 302. In this case, the first electronic component 201 and the second electronic component 202 may be disposed in the cavity CA, may be buried by the first insulating layer 111, and may protrude toward the outermost side.

The printed circuit board according to an example may have a through-via 130 penetrating the glass layer 110. The through-via 130 may penetrate the upper and lower surfaces of the glass layer 110, and a portion of the through-via 130 may protrude from the upper side of the glass layer 110. That is, the through-via 130 may have a through-portion penetrating the glass layer 110, and a protrusion portion protruding from the glass layer 110. In this case, the through-portion and the protrusion portion may be integrally formed.

The through-via 130 may include a metal. The metal may include copper (Cu), aluminum (Al), silver (Ag), tin (Sn), gold (Au), nickel (Ni), lead (Pb), titanium (Ti), or alloys thereof, and may preferably include copper (Cu), but the present disclosure not limited thereto. The through-via 130 may further include an electrolytic plating layer (or electrolytic copper), but the present disclosure not limited thereto, and may further include an electroless plating layer (or chemical copper) disposed along an inner wall of a through-hole. A sputtering layer may be included instead of the electroless plating layer (or chemical copper), and both may be included, as necessary. However, the present disclosure is not limited thereto, and the through-via 130 may include a sintered layer and/or a fired layer. The through-via 130 may be preferably formed by performing electrolytic plating using a carrier seed, but may also be formed by performing electroplating after performing electroless plating and/or sputtering on a via hole, or may also be formed by filling paste including a metal material, and then sintering and firing the paste.

The through-via 130 may protrude from the upper surface of the glass layer 110, and may not protrude from the lower surface of the glass layer 110. That is, an upper surface of the through-via 130 may be positioned to be higher than the upper surface of the glass layer 110, and the through-portion of the through-via 130 may protrude from the upper side of the glass layer 110. In addition, a lower surface of the through-via 130 may be substantially coplanar with the lower surface of the glass layer 110. Accordingly, in the printed circuit board according to an example, an upper side of the through-via 130 may protrude further than the glass layer 110, and a lower side of the through-via 130 may be substantially coplanar with the glass layer 110.

Such a configuration may be a result of attaching the glass layer 110 having a through-hole to a resist, further removing a portion of the resist corresponding to the through-hole, and then forming a through-via, in an operation of forming the through-via 130. Accordingly, on a side of the through-via 130 on which the resist is formed, the through-via 130 may protrude, and on a side opposite to the side of the through-via 130 on which the resist is formed, the through-via 130 may have a surface substantially coplanar with the glass layer 110. Such a configuration may be a structural difference that may occur in a method of manufacturing the glass layer 110 and the through-via 130, may be different from a structure of a through-via having both sides protruding further than a surface of the glass layer, and may be different from a structure of a through-via having both sides coplanar with a glass layer.

The through-via 130 of the printed circuit board according to an example may have the protrusion portion protruding from the upper side of the glass layer 110, such that the through-via 130 may be connected to other electronic components. In particular, the through-via 130 may protrude further than the glass layer 110, and thus may also perform a function of a post. That is, the upper side of the through-via 130 may protrude further than the glass layer 110, and thus may be easily bonded to an electronic component such as a semiconductor chip or the like. The lower surface of the through-via 130 may be substantially coplanar with the lower surface of the glass layer 110, such that bends or irregularities may not occur in an operation of forming a build-up layer by stacking the first insulating layer 111 and/or the second insulating layer 112. Accordingly, undulation may be prevented from occurring in the build-up operation, and flatness may be improved.

In the through-via 130 of the printed circuit board according to an example, in cross section, a width of an uppermost side of the through-portion may be substantially equal to a width of a lowermost side of the protrusion portion. The width of the uppermost side of the through-portion and the width of the lowermost side of the protrusion portion may be measured by imaging a cross-section of the printed circuit board taken in a stacking direction so as to penetrate a central axis of the via, using a scanning electron microscope or the like. The width of the uppermost side of the through-portion substantially equal to the width of the lowermost side of the protrusion portion may mean that the through-portion and the protrusion portion are continuously formed. Such a configuration may be a result of disposing the glass layer 110 having a first through-hole on a resist, forming a second through-hole penetrating the resist and forming the through-via 130 to simultaneously fill the first through-hole and the second through-hole. In this case, after the glass layer 110 having the first through-hole is formed on the resist, the second through-hole may be formed to correspond to the first through-hole, such that a width of the first through-hole and a width of the second through-hole at a boundary between the first through-hole and the second through-hole may be substantially equal to each other. Accordingly, widths of the protrusion portion and the through-portion of the through-via 130 at a boundary between the protrusion portion and the through-portion may be substantially equal to each other, such that the through-portion and the protrusion portion may be integrally formed. Such a configuration may be different from a land portion being formed in an operation of forming the through-via 130 in the glass layer 110, and the through-via 130 of the printed circuit board according to an example may not extend to be in contact with the upper surface of the glass layer 110. However, such a configuration may be different from the land portion being formed on the upper surface of the glass layer 110, and may not include an arrangement caused by an error or the like in a manufacturing operation occurring when the second through-hole formed in the resist has a width wider than that of the first through-hole formed in the glass layer 110.

The through-portion and the protrusion portion of the through-via 130 may be integrally formed. That is, the through-portion and the protrusion portion of the through-via 130 may be integrally formed by forming the through-via 130 to simultaneously fill through-holes formed in a resist and a glass layer and then removing the resist, rather than by forming the through-portion penetrating the glass layer 110, and then forming the protrusion portion protruding onto the glass layer 110 using another process. That is, the through-portion and the protrusion portion of the through-via 130 may be distinguished from each other for convenience depending on whether a position thereof is the inside or outside of the glass layer 110, and a boundary between the through-portion and the protrusion portion may not be visible.

The through-via 130 may have an upwardly tapered shape. In FIGS. 3A and 3B, it is illustrated that the through-via 130 has a substantially upwardly tapered shape, but the present disclosure is not necessarily limited thereto, and the through-via 130 may have a shape substantially the same as that of the cavity CA. Here, the through-via 130 having a shape substantially the same as that of the cavity CA may mean that a direction in which the through-via 130 is tapered is approximately the same as a direction in which the cavity CA is tapered when a polished or cut cross-section of the printed circuit board is observed using a scanning electron microscope or optical microscope, and relations among the widths of an upper side, a central side, and a lower side of the through-via 130 are similar to relations among the widths of an upper side, a central side, and a lower side of the cavity CA. Such a configuration may be a result of performing an operation of forming the cavity CA in the glass layer 110 simultaneously with an operation of forming a through-hole in the glass layer 110 to form the through-via 130. In this case, the through-portion and the protrusion portion of the through-via 130 may be integrally formed in the same operation, such that the through-portion and the protrusion portion of the through-via 130 may be substantially tapered in a predetermined direction, and may substantially have a predetermined degree of being tapered. Such a configuration may mean that the through-portion and the protrusion portion may have a tapered shape so as to have substantially the same inclination with respect to the upper surface of the glass layer.

In the printed circuit board according to an example, the protrusion portion of the through-via 130 may not be formed by removing a portion of the upper surface of the glass layer 110, such that the upper and lower surfaces of the glass layer 110 may have substantially the same surface roughness. However, the present disclosure is not necessarily limited thereto, and the lower surface of the glass layer 110 may be processed to be substantially coplanar with the lower surface of the through-via 130, such that the lower surface of the glass layer 110 may have a surface roughness different from that of the lower surface of the through-via 130. However, even in this case, the surface roughness may not be formed by processing the upper surface of the glass layer 110.

The first electronic component 201 and/or the second electronic component 202 may be mounted in the cavity CA of the glass layer 110. The first electronic component 201 and the second electronic component 202 may be various types of electronic components, and may be active components and/or passive components. The active components may be various types of integrated circuit (IC) dies in which hundreds to millions of circuits are integrated into a single chip. The passive components may be chip-type capacitors such as multilayer ceramic capacitors (MLCCs) such as silicon capacitors, or chip-type inductors such as power inductors (PIs). However, the present disclosure is not limited thereto, and other types of active components and/or passive components may be disposed. In addition, the first electronic component 201 and/or the second electronic component 202 may be a bridge for die-to-die interconnection. The bridge may be a silicon bridge or may be in the form of a semiconductor chip in which a fine circuit is implemented on a silicon wafer. However, the present disclosure is not limited thereto, the first electronic component 201 and/or the second electronic component 202 may be an organic bridge including an organic insulating material. As such, there is no limitation to the first electronic component 201 and the second electronic component 202, and any component or device being connected to the printed circuit board, such as being mounted on the printed circuit board or being buried in the printed circuit board, to perform a function thereof may be used without limitation. The first electronic component 201 and the second electronic component 202 may be connected to different semiconductor chips or may be connected to a single semiconductor chip to exchange power or signals.

The first electronic component 201 and the second electronic component 202 may respectively include a metal pillar 203. The metal pillar 203 may include a metal. The metal may include copper (Cu), aluminum (Al), silver (Ag), tin (Sn), gold (Au), nickel (Ni), lead (Pb), titanium (Ti), and/or alloys thereof. The metal may preferably include copper (Cu), but the present disclosure is not limited thereto.

In the same manner as the through-via 130, at least a portion of the metal pillar 203 may protrude from the printed circuit board. That is, the metal pillar 203 may protrude from the first insulating layer 111, a component in which the metal pillar 203 is buried, and thus may function as a path for electrical connection to other components. That is, the metal pillar 203 may protrude further than the first insulating layer 111, and an upper surface of the metal pillar 203 may be positioned to be higher than an upper surface of the first insulating layer 111 and the upper surface of the glass layer 110, and thus may have a protruding structure. In addition, the upper surface of the metal pillar 203 may be substantially coplanar with the upper surface of the through-via 130. That is, in the printed circuit board, the through-via 130 and the metal pillar 203 may respectively function as a means for connection to a semiconductor chip, such that the through-via 130 and the metal pillar 203 having protruding surfaces having the same height may be advantageous for connection to other components such as a semiconductor chip and the like. The printed circuit board according to an example may be a result of forming the through-via 130 after the first electronic component 201 and the second electronic component 202 are mounted after the glass layer having the cavity CA is formed on the resist, and forming a recess in which a portion of the through-via 130 is removed in an operation of removing a seed of a carrier board, and performing a grinding or polishing process such that the upper surface of the through-via 130 and the upper surface of the metal pillar 203 are substantially coplanar with each other in an operation of removing the resist. Such a configuration will be described below in more detail in connection with a method of manufacturing a printed circuit board.

In FIGS. 3A and 3B, it is illustrated that upper sides of the first electronic component 201 and the second electronic component 202 respectively include the metal pillar 203 and lower sides of the first electronic component 201 and the second electronic component 202 are respectively connected to the first via layer 131. Accordingly, both upper and lower surfaces of the first electronic component 201 and the second electronic component 202 are illustrated as active surfaces respectively, but the present disclosure is not limited thereto, and the upper sides of the first electronic component 201 and the second electronic component 202 may be respectively active surfaces, and the lower sides of the first electronic component 201 and the second electronic component 202 may be respectively inactive surfaces. In this case, lower surfaces of the electronic components, inactive surfaces, may not be connected to the first via layer 131, but may be connected to the outside through the metal pillar 203 positioned on the upper sides of the electronic components. The present disclosure is not limited thereto, and the first electronic component 201 and the second electronic component 202 may respectively have only the lower surface as an active surface. In this case, the electronic component may not include the metal pillar 203. In this case, the electronic component may not be directly connected to the outside, but may be connected through other wirings of the printed circuit board.

The first insulating layer 111 may fill the cavity CA, and may be disposed to extend to the lower surface of the glass layer 110 and thus may be disposed on the glass layer 110. That is, the first insulating layer 111 may be a build-up layer disposed on the glass layer 110, may be formed to fill the cavity CA to cover at least a portion of the first electronic component 201 and the second electronic component 202 disposed in the cavity CA, and may be disposed on the lower surface of the glass layer 110.

The first insulating layer 111 may include an organic insulating material. The organic insulating material may include a thermosetting resin such as an epoxy resin, a thermoplastic resin such as polyimide, or a material including an inorganic filler, an organic filler, and/or a glass fiber (glass cloth, and/or glass fabric), together with a resin. The insulating material may be a non-photosensitive material such as an Ajinomoto build-up film (ABF), prepreg (PPG), or the like, but the present disclosure is not limited thereto, and other polymer materials may be used. In addition, the insulating material may be a photosensitive insulating material such as photoimageable dielectric (PID) or the like. In addition, the insulating material may include an adhesive sheet such as a bonding sheet (BS) or the like.

An upper surface of the first insulating layer 111 may be substantially coplanar with the upper surface of the glass layer 110. Referring to FIGS. 3A and 3B, the upper surface of the first insulating layer 111 may refer to an upper surface of a portion of the first insulating layer 111, filling the cavity CA of the glass layer 110, and may refer to an upper surface of a portion of the first insulating layer 111, adjacent to the upper surface of the glass layer 110 and externally exposed. In a method of manufacturing a printed circuit board, a resist may be formed on a carrier board, then the glass layer 110 having the cavity CA may be formed, and then the first insulating layer 111 may be formed to fill the cavity CA, such that the upper surface of the first insulating layer 111 may not be formed beyond the resist exposed by the cavity CA. Accordingly, the upper surface of the first insulating layer 111 may be substantially coplanar with the upper surface of the glass layer 110.

In the printed circuit board according to an example, the protrusion portion of the through-via 130 may not be formed by removing a portion of the upper surface of the first insulating layer 111, such that the upper surface of the first insulating layer 111 may have a surface roughness substantially the same as that of a side surface of the first insulating layer 111 or a lower surface of the first insulating layer 111, disposed on an inner wall of the cavity CA. However, the present disclosure is not necessarily limited thereto, and the lower surface of the first insulating layer 111 may be processed to be substantially coplanar with the lower surface of the through-via 130, such that the lower surface of the first insulating layer 111 may have a surface roughness different from that of the lower surface of the through-via 130. However, even in this case, the surface roughness may not be formed by processing the upper surface of the first insulating layer 111.

The printed circuit board according to an example may include a first wiring layer 121 disposed on the first insulating layer 111, and a first via layer 131 penetrating at least a portion of the first insulating layer 111. The first via layer 131 may be a component for connecting the first wiring layer 121 and the through-via 130 to each other, and at least a portion of the first via layer 131 may be in contact with the through-via 130. That is, the first via layer 131 may be disposed on the lower surface of the glass layer 110, and thus may be distinguished from the through-via 130, and the first via layer 131 and the through-via 130 may have a boundary surface therebetween.

The first wiring layer 121 may include a metal. The metal may include copper (Cu), aluminum (Al), silver (Ag), tin (Sn), gold (Au), nickel (Ni), lead (Pb), titanium (Ti), and/or alloys thereof. The metal may preferably include copper (Cu), but the present disclosure is not limited thereto. The first wiring layer 121 may perform various functions depending on a design thereof. For example, the first wiring layer 121 may include a signal pattern, a power pattern, a ground pattern, and the like, but the present disclosure is not limited thereto. Each of the above-described patterns may have various forms such as a line, a plane, a pad, and the like. The first wiring layer 121 and the second wiring layer 122 may include an electroless plating layer (or chemical copper) and an electrolytic plating layer (or electrolytic copper), respectively. Alternatively, the first wiring layer 121 and the second wiring layer 122 may include a metal foil (or copper foil) and an electrolytic plating layer (or electrolytic copper). Alternatively, the first wiring layer 121 and the second wiring layer 122 may include a metal foil (or copper foil), an electroless plating layer (or chemical copper), and an electrolytic plating layer (or electrolytic copper). A sputtering layer may be included instead of the electroless plating layer (or chemical copper), and both may be included, as necessary.

The first wiring layer 121 may be formed using one of a semi-additive process (SAP), a modified semi-additive process (MSAP), tenting (TT), or a subtractive process, but the present disclosure is not limited thereto, and any method capable of forming a circuit in a printed circuit board may be used without limitation. In addition, the first wiring layer 121 may be formed using different methods depending on a purpose and design thereof.

The first via layer 131 may include a metal. The metal may include copper (Cu), aluminum (Al), silver (Ag), tin (Sn), gold (Au), nickel (Ni), lead (Pb), titanium (Ti), and/or alloys thereof. The metal may preferably include copper (Cu), but the present disclosure is not limited thereto. The first via layer 131 may include a filled via filling a via hole, or a conformal via disposed along a wall surface of the via hole. The first via layer 131 may perform various functions depending on a design thereof. For example, a ground via, a power via, a signal via, and the like may be included.

At least a portion of the first via layer 131 may connect the through-via 130 and the first wiring layer 121 to each other, and a portion of the first via layer 131 may connect the first electronic component 201 or the second electronic component 202 and the first wiring layer 121 to each other. In this case, the first via layer 131 may be connected to upper and lower sides of the first electronic component 201 or the second electronic component 202, and upper and lower surfaces of the first electronic component 201 or the second electronic component 202 may be active surfaces. However, the present disclosure is not necessarily limited thereto, and the first via layer 131 may not be connected to the first electronic component 201 or the second electronic component 202. In this case, the upper side of the first electronic component 201 or the second electronic component 202 may be an active surface. In this case, the upper side of the first electronic component 201 or the second electronic component 202 may be directly connected to a device such as a semiconductor chip or the like. A portion of the first via layer 131 and the first wiring layer 121, connected to the first electronic component 201 or the second electronic component 202, may have a structure finer than that of another portion of the first via layer 131 and the first wiring layer 121, connected to the through-via 130, but the present disclosure is not necessarily limited thereto.

The printed circuit board according to an example may further include a second insulating layer 112 disposed on the first insulating layer 111, a second wiring layer 122 disposed on the second insulating layer 112, and a second via layer 132 penetrating at least a portion of the second insulating layer 112 to connect the second wiring layer 122 and the first wiring layer 121 to each other or to connect the second wiring layers 122 to each other.

The second insulating layer 112 may include an organic insulating material. The organic insulating material may include a thermosetting resin such as an epoxy resin, a thermoplastic resin such as polyimide, or a material including an inorganic filler, an organic filler, and/or a glass fiber (glass cloth, and/or glass fabric), together with the above-described resins. The insulating material may be a non-photosensitive material such as an Ajinomoto build-up film (ABF), prepreg (PPG), or the like, but the present disclosure is not limited thereto, and other polymer materials may be used. In addition, the insulating material may be a photosensitive insulating material such as photoimageable dielectric (PID) or the like. In addition, the insulating material may include an adhesive sheet such as a bonding sheet (BS) or the like. The second insulating layer 112 may include an insulating material substantially the same as that of the first insulating layer 111, and the first insulating layer 111 and the second insulating layer 112 may be respectively disposed as a build-up insulating layer for build-up. However, the present disclosure is not limited thereto, and the first insulating layer 111 and the second insulating layer 112 may include different insulating materials.

The second wiring layer 122 may include a metal. The metal may include copper (Cu), aluminum (Al), silver (Ag), tin (Sn), gold (Au), nickel (Ni), lead (Pb), titanium (Ti), and/or alloys thereof. The metal may preferably include copper (Cu), but the present disclosure is not limited thereto. The second wiring layer 122 may perform various functions depending on a design thereof. For example, the second wiring layer 122 may include a signal pattern, a power pattern, a ground pattern, and the like, but the present disclosure is not limited thereto. Each of the above-described patterns may have various forms such as a line, a plane, a pad, and the like. The second wiring layer 122 may include an electroless plating layer (or chemical copper) and an electrolytic plating layer (or electrolytic copper). Alternatively, the second wiring layer 122 may include a metal foil (or copper foil) and an electrolytic plating layer (or electrolytic copper). Alternatively, the second wiring layer 122 may include a metal foil (or copper foil), an electroless plating layer (or chemical copper), and an electrolytic plating layer (or electrolytic copper). A sputtering layer may be included instead of the electroless plating layer (or chemical copper), and both may be included, as necessary.

The second via layer 132 may include a metal. The metal may include copper (Cu), aluminum (Al), silver (Ag), tin (Sn), gold (Au), nickel (Ni), lead (Pb), titanium (Ti), and/or alloys thereof. The metal may preferably include copper (Cu), but the present disclosure is not limited thereto. The second via layer 132 may include a filled via filling a via hole, or a conformal via disposed along a wall surface of the via hole. The second via layer 132 may perform various functions depending on a design thereof. For example, a ground via, a power via, a signal via, and the like may be included. The second via layer 132 may include an electroless plating layer (or chemical copper) and an electrolytic plating layer (or electrolytic copper). A sputtering layer may be included instead of the electroless plating layer (or chemical copper), and both may be included, as necessary.

The second wiring layer 122 and the second via layer 132 may be respectively formed using one of an SAP, an MSAP, TT, or a subtractive process, but the present disclosure is not limited thereto, and any method capable of forming a circuit in a printed circuit board may be used without limitation.

The printed circuit board according to an example may further include a solder resist layer 140 on the second insulating layer 112. The solder resist layer 140 may be disposed on an outermost side of the printed circuit board to externally protect the printed circuit board. A known solder resist may be used as the solder resist layer 140, and the solder resist layer 140 may include a liquid or film-type solder resist, but the present disclosure is not limited thereto, and other types of insulating materials may be used. The solder resist layer 140 may include a thermosetting resin and an inorganic filler dispersed in the thermosetting resin, but may not include a glass fiber. An insulating resin may be a photosensitive insulating resin, and a filler may be an inorganic filler and/or an organic filler, but the present disclosure is not limited thereto, and other polymer materials may be used, as necessary. The solder resist layer 140 may have an opening, and at least a portion of the second wiring layer 122 may be exposed through the opening. The second wiring layer 122 exposed through the opening may be connected to a device such as a semiconductor chip or the like, and may also be connected to a motherboard, a main board, or another printed circuit board. An wiring layer exposed through the opening may function as a pad, and a surface treatment layer may be further formed on the pad, as necessary.

In the printed circuit board according to the example, it is illustrated that the second insulating layer 112 and the second wiring layer 122 respectively include four layers, but the number of layers of the second insulating layer 112 and the second wiring layer 122 may vary.

Referring to FIG. 3B, the through-via 130 may be connected to the first semiconductor chip 301 and the second semiconductor chip 302 through a connection member 400. The first semiconductor chip 301 and the second semiconductor chip 302 may be directly connected to the through-portion of the through-via 130 and the metal pillar 203. In this case, a portion of the first semiconductor chip 301 may be connected to the through-via 130, and another portion of the first semiconductor chip 301 may be connected to the first electronic component 201 through the metal pillar 203. In addition, a portion of the second semiconductor chip 302 may be connected to the through-via 130, another portion of the second semiconductor chip 302 may be connected to the first electronic component 201 through the metal pillar 203, and another portion of the second semiconductor chip 302 may be connected to the second electronic component 202 through the metal pillar 203. That is, the first semiconductor chip 301 and the second semiconductor chip 302 may be electrically connected to each other through the first electronic component 201. In this case, the first electronic component 201 may function as a bridge connecting the first semiconductor chip 301 and the second semiconductor chip 302 to each other, and the second electronic component 202 may be connected to the second semiconductor chip 302, and thus may be used to supply power to the second semiconductor chip 302.

The first semiconductor chip 301 and the second semiconductor chip 302 may respectively include an integrated circuit (IC) die in which hundreds to millions of devices are integrated into a single chip. In this case, the integrated circuit may be, for example, a logic chip such as a central processing unit (for example, a CPU), a graphics processing unit (for example, a GPU), a field programmable gate array (FPGA), a digital signal processor, a cryptographic processor, a microprocessor, a microcontroller, an application processor (for example, an AP), an analog-to-digital converter, or the like, but the present disclosure is not limited thereto, and may also be a memory chip such as a volatile memory (for example, DRAM), a non-volatile memory (for example, ROM), a flash memory, a high bandwidth memory (HBM), or the like, or a power management IC (PMIC) or the like. For example, the first semiconductor chip 301 may include a logic chip such as a GPU, and the second semiconductor chip 302 may include a memory chip such as an HBM. Alternatively, the first semiconductor chip 301 and the second semiconductor chip 302 may be logic chips divided by die split, the divided logic chips having different cores.

The first semiconductor chip 301 and the second semiconductor chip 302 may be respectively formed based on an active wafer. In this case, silicon (Si), germanium (Ge), gallium arsenide (GaAs), or the like may be used as a base material included in each body. Various circuits may be formed in the body. A connection pad may be formed on each body, and the connection pad may include a conductive material such as aluminum (Al), copper (Cu), or the like. The first semiconductor chip 301 and the second semiconductor chip 302 may be bare dies. In this case, a metal bump may be disposed on the connection pad. The first semiconductor chip 301 and the second semiconductor chip 302 may be packaged dies. In this case, a redistribution layer may be additionally formed on the connection pad, and a metal bump may be disposed on the redistribution layer.

The first semiconductor chip 301 and the second semiconductor chip 302 may be connected to the through-via 130 and/or the metal pillar 203 through the connection member 400. The connection member 400 may be formed of a low melting point metal, for example, solder such as tin (Sn)-aluminum (Al)-copper (Cu) or the like, but the present disclosure is not limited thereto. The connection member 400 may be formed of multiple layers or a single layer. When formed of multiple layers, the connection member 400 may include a copper pillar and solder. When formed of a single layer, the connection member 400 may include tin-silver solder or copper, but the present disclosure is not limited thereto. In addition, any means, serving as an intermediary such that a semiconductor chip or electronic component is mounted on and connected to a printed circuit board, may be used without limitation. In FIG. 3B, two semiconductor chips are illustrated as being mounted, but the present disclosure is not limited thereto. A larger number of semiconductor chips may be mounted, and a larger number of semiconductor chips may also be die-to-die connected to each other by the first electronic component 201.

The printed circuit board according to an example is not limited to the components illustrated in FIGS. 3A and 3B, and may further include a general component of the printed circuit board. That is, the printed circuit board may further include a component that could be used by those skilled in the art. For example, the printed circuit board may further include a means for protecting the glass layer disposed on the uppermost side thereof, or may further include a component for improving bonding strength with a semiconductor chip by performing surface treatment on the protrusion portion of the through-via 130 and a protrusion portion of the metal pillar 203.

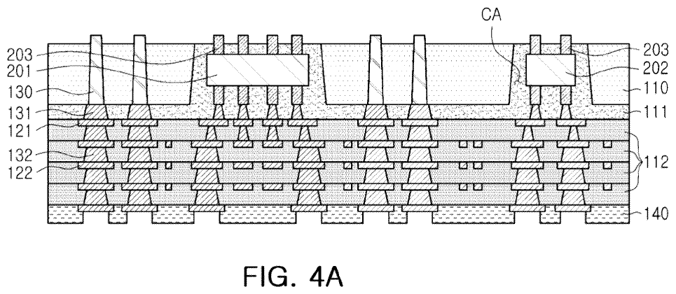

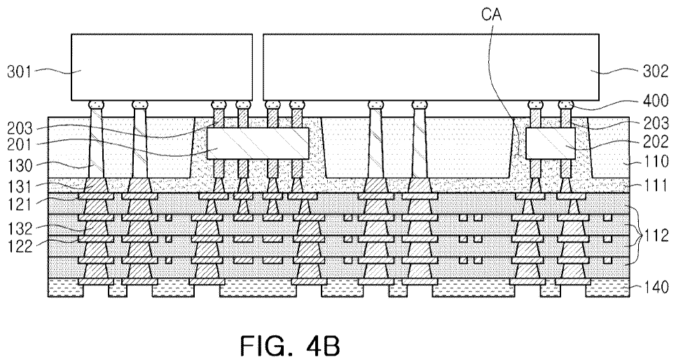

FIGS. 4A and 4B are schematic cross-sectional views of a printed circuit board according to another example.

Referring to FIGS. 4A and 4B, an upper side and a lower side of each of a first electronic component 201 and/or a second electronic component 202 of a printed circuit board according to another example may respectively include a metal pillar 203. That is, both surfaces of each of the first electronic component 201 and/or the second electronic component 202 of the printed circuit board according to another example may be active surfaces, and the metal pillar 203, disposed on the lower side of each of the first electronic component 201 and/or the second electronic component 202, may be connected to a first wiring layer 121 through a first via layer 131. In this case, after the first electronic component 201 and/or the second electronic component 202 are mounted in a cavity CA and embedded by the first insulating layer 111, the first via layer 131 and the first wiring layer 121 may be formed, such that connection to the first wiring layer 121 may be performed. Accordingly, the metal pillar 203, disposed on the lower side of each of the first electronic component 201 and/or the second electronic component 202, may be disposed to be in contact with the first via layer 131, and the metal pillar 203 and the first via layer 131 may be directly connected to each other.

A description of the printed circuit board according to another example of FIGS. 4A and 4B, excluding a description of the first electronic component 201 and the second electronic component 202, may be applied in the same manner as a description of the printed circuit board according to an example, and thus repeated descriptions will be omitted.

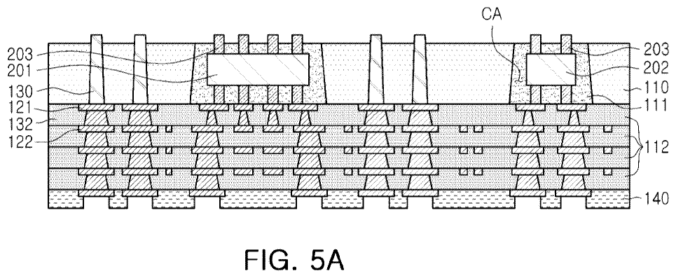

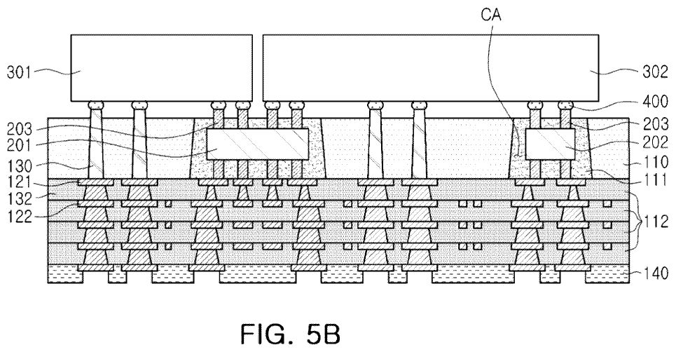

FIGS. 5A and 5B are schematic cross-sectional views of a printed circuit board according to another example.

Referring to FIGS. 5A and 5B, in the printed circuit board according to another example, a first via layer 131 may be omitted, such that a through-via 130 and a metal pillar 203 may be directly connected to a first wiring layer 121. That is, the through-via 130 and the metal pillar 203 may be disposed to be in contact with the first wiring layer 121.

Such a configuration may be a result of a first electronic component 201 and a second electronic component 202 being mounted in a cavity CA and being buried by a first insulating layer 111, and then the first insulating layer 111 and a glass layer 110 being planarized. When the first insulating layer 111 is planarized by removing a portion of the first insulating layer 111 disposed on the glass layer 110, the first wiring layer 121 may be directly formed on the through-via 130 and the metal pillar 203. That is, the first insulating layer 111 may be formed to fill the cavity CA, and may not extend onto a lower surface of the glass layer 110. A lower surface of the first insulating layer 111 may be substantially coplanar with the lower surface of the glass layer 110. In the printed circuit board according to another example, the first wiring layer may be omitted, such that an overall thickness of the printed circuit board may be reduced, thereby implementing a thinner printed circuit board. In this case, the printed circuit board may include the glass layer 110, such that, in an operation of planarizing the first insulating layer 111, flatness may be ensured by the glass layer 110, and processing stability may be achieved.

A description of the printed circuit board according to another example of FIGS. 5A and 5B, excluding a description of the first insulating layer 111 and the first wiring layer 121, may be applied in the same manner as a description of the printed circuit board according to an example and a description of the printed circuit board according to another example, and thus repeated descriptions will be omitted.

### Method of Manufacturing Printed Circuit Board

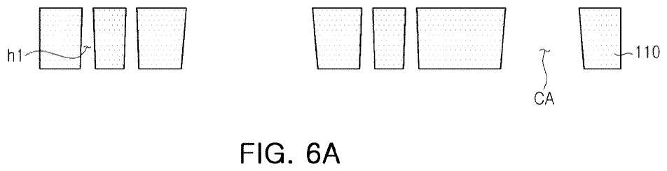

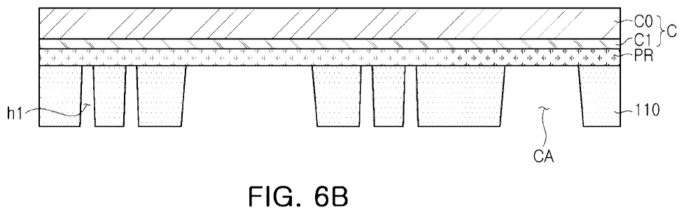

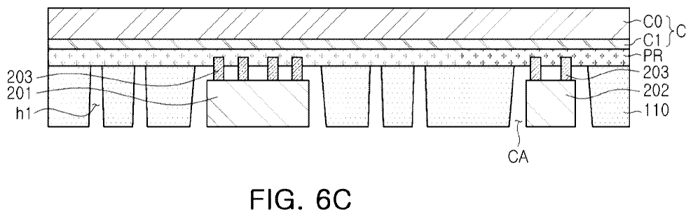

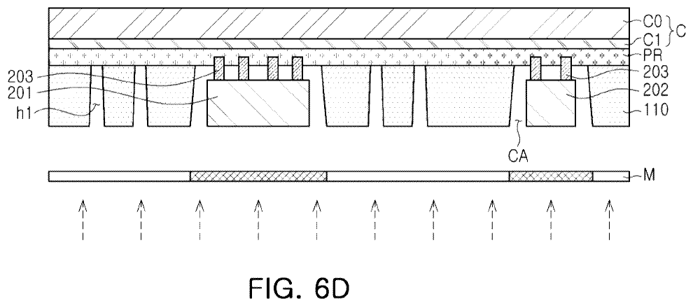

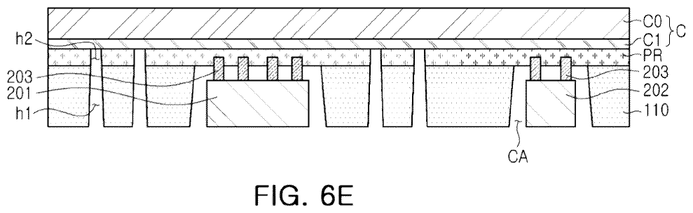

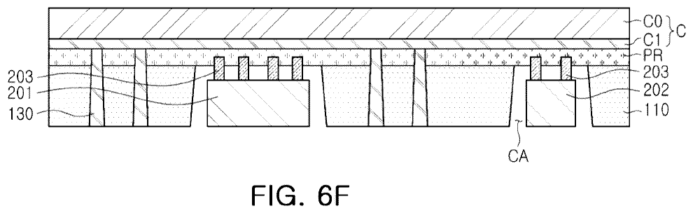

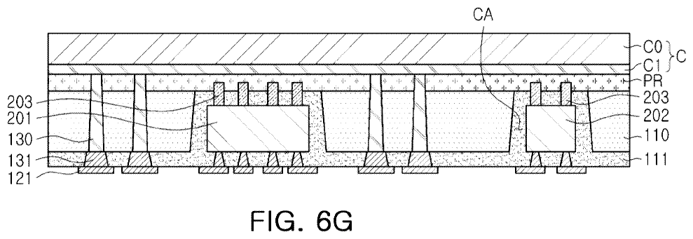

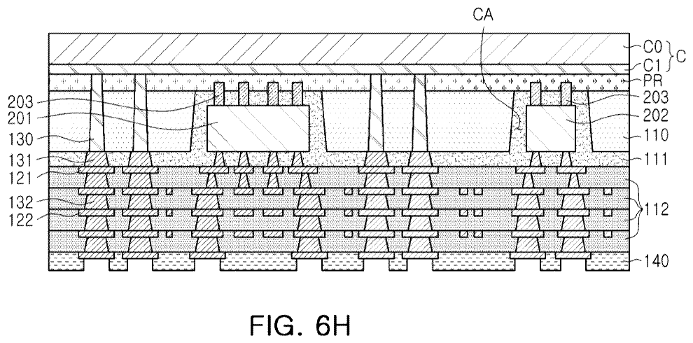

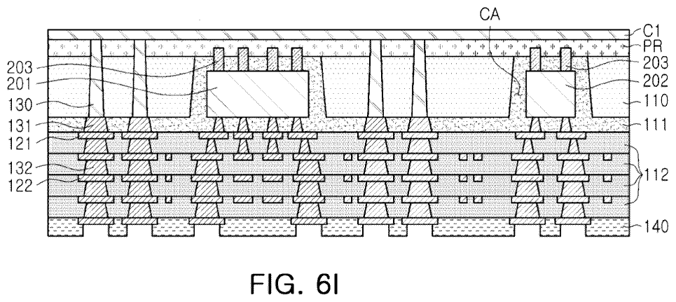

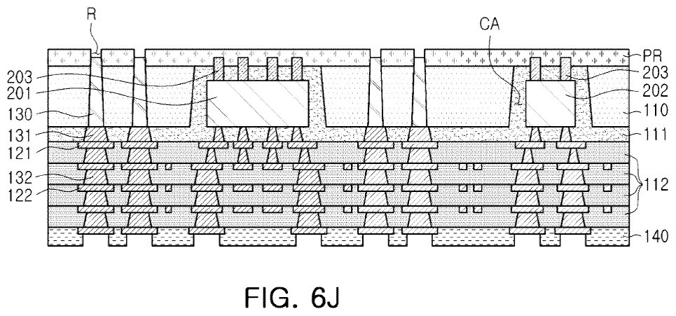

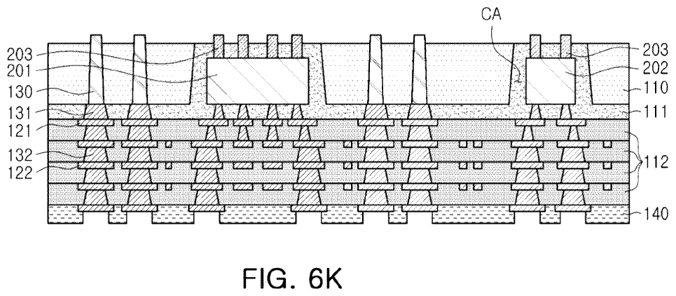

FIGS. 6A to 6K are schematic cross-sectional views of a method of manufacturing a printed circuit board according to an example.

Referring to FIG. 6A, the method of manufacturing the printed circuit board may include an operation of forming a first through-hole h1 and a cavity CA in a glass layer 110.

The first through-hole h1 may be a position in which a through-portion of the through-via 130 is formed, and the cavity CA may be a region in which a first electronic component 201 and a second electronic component 202 are mounted. In this case, in FIG. 6A, it is illustrated that the first through-hole h1 and the cavity CA have an upwardly tapered shape. That is, it is illustrated that the first through-hole h1 and the cavity CA are formed from bottom to top, but the present disclosure is not limited thereto, and the first through-hole h1 and the cavity CA may have a downwardly tapered shape, or the first through-hole h1 and the cavity CA may have both sides having a tapered shape in a direction of a central portion thereof, as described above. Any method of forming the first through-hole h1 and the cavity CA by processing the glass layer 110 may be used without limitation. For example, any processing method for forming a through-glass via (TGV) may be used without limitation.

Referring to FIG. 6B, the method of manufacturing the printed circuit board may include an operation of forming a resist PR on a carrier board C, and then bonding the glass layer 110 to the resist PR.

The carrier board C may be used to support an insulating layer and an wiring layer when the insulating layer and the wiring layer are formed, and may be formed of an insulating material or a metal material. In FIG. 6B, it is illustrated that the carrier board C includes an insulating material C0 and a seed C1 disposed on a lower side of the insulating material C0, but the present disclosure is not necessarily limited thereto, and an upper side and a lower side of the insulating material C0 may respectively include the seed C1. That is, the carrier board C is merely an example, and any suitable carrier board C could be used by those skilled in the art. In the present disclosure, any component, used as a support board and detached or removed in a subsequent process, may be used without limitation.

A known dry film may be used as the resist PR, and any material including a photosensitive insulating material, any material capable of forming a second through-hole having a portion removed using exposure and development processes in a subsequent operation may be used without limitation. The resist PR may preferably include a positive-type photosensitive insulating material. When the positive-type photosensitive insulating material is included, a photopolymer-polymer bond may be broken in an exposed portion, and the portion in which the photopolymer-polymer bond is broken may be removed in a subsequent development process, such that it may be more suitable to form a second through-hole h2 (see, e.g., FIG. 6E) in a region corresponding to a region in which first through-hole h1 is formed. The resist PR may be formed on a lower surface of the carrier board C using laminating, and may be bonded to the glass layer 110 by attaching the glass layer 110 before the resist PR is cured, but the present disclosure is not necessarily limited thereto. An adhesive means may be further included between the resist PR and the glass layer 110 to bond the glass layer 110 and the resist PR to each other.

Referring to FIG. 6C, the method of manufacturing the printed circuit board may include an operation of disposing a first electronic component 201 and a second electronic component 202 in the cavity CA. The first electronic component 201 and the second electronic component 202 may be mounted on the resist PR positioned in the cavity CA. In this case, the resist PR may be in a state before being cured, such that when the first electronic component 201 and the second electronic component 202 are mounted, the metal pillar 203 may protrude further than an upper surface of the cavity CA, a mounting surface. That is, at least a portion of the resist PR may be recessed, as if the first electronic component 201 and the second electronic component 202 penetrate at least a portion of the resist PR. Thereafter, an operation of curing the resist PR may be performed, and the electronic components and the glass layer 110 may be disposed and fixed to the resist PR.

Referring to FIG. 6D, the method of manufacturing the printed circuit board may include an operation of exposing the resist PR, e.g., to radiation such as ultraviolet (UV) light.

In this case, a mask M may be used to selectively expose the resist PR, and the resist PR may include the positive-type photosensitive insulating material, such that a region in which the second through-hole h2 is to be processed may be opened to expose the region. That is, a region in which the first electronic component 201 and the second electronic component 202 are disposed may have light blocked by the mask M, and may be exposed such that the second through-hole h2 may be formed to correspond to a region of the first through-hole h1. In FIG. 6D, it is illustrated that the mask M is disposed only in a region of the cavity CA, but the present disclosure is not necessarily limited thereto. Considering the transparency of the glass layer 110, only a region in which the first through-hole h1 is formed may be opened and remaining regions of the glass layer 110 may all be blocked by the mask M.

Referring to FIG. 6E, the method of manufacturing the printed circuit board may include an operation of developing the resist PR.

In this case, the resist PR in the exposed region may be removed to form the second through-hole h2. The second through-hole h2 may be formed to correspond to the first through-hole h1, and may be formed to penetrate an upper portion and a lower portion of the resist PR. As the second through-hole h2 penetrates the upper portion and the lower portion of the resist PR, the seed C1 may be exposed by the first through-hole h1 and the second through-hole h2.

Referring to FIG. 6F, the method of manufacturing the printed circuit board may include an operation of forming the through-via 130.

The through-via 130 may be formed by performing electrolytic plating using the seed C1 of the carrier board C as a plating seed. The resist PR may function as a plating resist, such that electrolytic plating may be performed only in the second through-hole h2, and the through-via 130 may be formed to fill the second through-hole h2 and the first through-hole h1. The metal pillar 203 of each of the first electronic component 201 and the second electronic component 202 may not completely penetrate the resist PR, such that the metal pillar 203 may not be in contact with the seed C1. Even in an operation of forming the through-via 130 using the seed C1, the metal pillar 203 may remain electrically disconnected by the resist PR. A method of forming the through-via 130 is not limited thereto, and the through-via 130 may be formed by performing electroless plating or sputtering to form a seed on inner walls of the first through-hole h1 and the second through-hole h2, and then performing electrolytic plating, or by filling a paste including a metal material and firing the paste. Any method of forming a through-via may be used without limitation.

Referring to FIG. 6G, the method of manufacturing the printed circuit board may include an operation of forming a first insulating layer 111, and an operation of forming a first wiring layer 121 and a first via layer 131.

The first insulating layer 111 may cover the first electronic component 201 and the second electronic component 202, and may fill the cavity CA. In this case, the first insulating layer 111 may also be disposed on the glass layer 110 to cover at least a portion of a lower surface of the glass layer 110. A known method of stacking an insulating layer may be used as a method of forming the first insulating layer 111.

After the first insulating layer 111 is formed, the first wiring layer 121 and the first via layer 131 mat be formed. A portion of the first via layer 131 may be in contact with the through-via 130, and another portion of the first via layer 131 may be in contact with the first electronic component 201 and the second electronic component 202. A known method of forming an interlayer connection and an wiring pattern may be used as a method of forming the first wiring layer 121 and the first via layer 131.

Referring to FIG. 6H, the method of manufacturing the printed circuit board may include an operation of forming a second insulating layer 112, a second wiring layer 122, and a second via layer 132, and an operation of forming a solder resist layer 140 on a lower side of the second insulating layer 112.

The second insulating layer 112, the second wiring layer 122, and the second via layer 132 may be formed using a known method of stacking a build-up layer of a printed circuit board, and a known method may be used a method of forming the solder resist layer 140.

Referring to FIGS. 61 and 6J, the method of manufacturing the printed circuit board may include an operation of removing the carrier board C. In the operation of removing the carrier board C, an operation of removing the insulating material C0 and an operation of removing the seed C1 may be performed in a stepwise manner separately or simultaneously.

Referring to FIG. 6I, the insulating material C0 of the carrier board C may be removed. A known method of removing an insulating layer and a known method of detaching the carrier board C may be used as a method of removing the insulating material C0 of the carrier board C.

Referring to FIG. 6J, the seed C1 of the carrier board C may be removed. A known method of removing a metal layer or metal foil may be used as a method of removing the seed C1. In this case, in an operation of removing the seed C1, a portion of the through-via 130 may be removed together by an etching solution or the like. However, the resist PR may not react in the operation of removing the seed C1, such that a recess R may be formed in a region in which a portion of the through-via 130 is removed. In this case, a depth of the recess R may be substantially equal to a distance between the metal pillar 203 and an upper surface of the resist PR, and an upper surface of the through-via 130 may be substantially coplanar with an upper surface of the metal pillar 203, but the present disclosure is not necessarily limited thereto.

Referring to FIG. 6K, the method of manufacturing the printed circuit board may include an operation of removing the resist PR.

The operation of removing the resist PR may be performed by exposing and developing the entire surface of the resist PR, but the present disclosure is not necessarily limited thereto, and any known method of removing a resist may be used without limitation.

After the resist PR is removed, an operation of planarizing protrusion portions of the through-via 130 and the metal pillar 203 may be further included. As a result, the through-via 130 and the metal pillar 203 may be substantially coplanar with each other.

FIGS. 6A to 6K illustrate an operation of manufacturing the printed circuit board only with respect to a lower side of the carrier board C, but the seed C1 may also be disposed on an upper side of the insulating material C0 of the carrier board C, such that the printed circuit board may be formed on both surfaces of the carrier board C. In this case, another board that is symmetrical to the printed circuit board with respect to the carrier board C may be further manufactured using the method of manufacturing the printed circuit board.

The method of manufacturing the printed circuit board according to an example is not limited to those illustrated in FIGS. 6A to 6K, and may further include a method of forming a component that could be used by those skilled in the art.

A method of manufacturing a printed circuit board according to another example may be different from the method of manufacturing the printed circuit board according to an example in terms of whether an upper side and a lower side of each of a first electronic component 201 and a second electronic component 202 include a metal pillar 203. The method of manufacturing the printed circuit board according to another example may be performed in the same manner as the method of manufacturing the printed circuit board according to an example, and thus a detailed description thereof will be omitted.

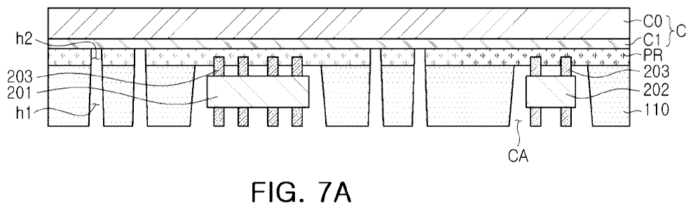

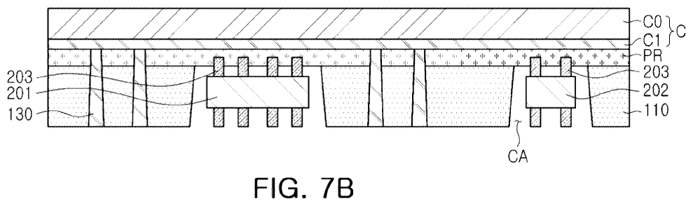

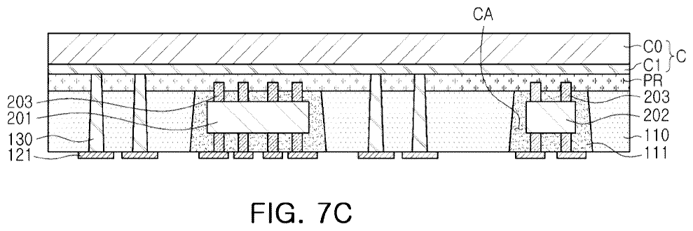

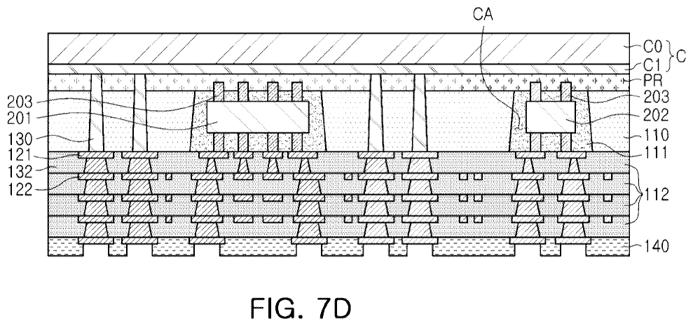

FIGS. 7A to 7D are schematic cross-sectional views of a portion of a method of manufacturing a printed circuit board according to another example. FIGS. 7A to 7D may respectively correspond to FIGS. 6E to 6H in the method of manufacturing the printed circuit board according to an example. The printed circuit board according to another example may be different from the printed circuit board according to an example in terms of whether a first electronic component 201 and a second electronic component 202 include a metal pillar 203, an arrangement of a first insulating layer 111, omission of a first via layer 131, and an arrangement of a first wiring layer 121.

Referring to FIG. 7A, in the printed circuit board according to another example, an upper side and a lower side of each of a first electronic component 201 and a second electronic component 202 may include a metal pillar 203. A description of the method of manufacturing the printed circuit board according to an example may be applied to a method of disposing the first electronic component 201 and the second electronic component 202 in a cavity CA and forming a second through-hole h2 in the same manner.

Referring to FIG. 7B, a through-via 130 may be formed, and a description of the method of manufacturing the printed circuit board according to an example may be applied in the same manner.

Referring to FIG. 7C, the method of manufacturing the printed circuit board according to another example may include an operation of forming a first insulating layer 111, and an operation of forming a first wiring layer 121 on a lower surface of a glass layer 110 and a lower surface of the first insulating layer 111.

The operation of forming the first insulating layer 111 may be performed by removing a portion of the first insulating layer 111 disposed on a lower side of the glass layer 110 after stacking the first insulating layer 111. That is, the operation may be performed by removing a portion of the first insulating layer 111 protruding toward a lower surface of the glass layer 110 after stacking the first insulating layer 111. Accordingly, the first insulating layer 111 may be disposed to fill the cavity CA, and a lower surface of the first insulating layer 111 may be formed to be substantially coplanar with the lower surface of the glass layer 110. In this case, a portion of the first insulating layer 111 may be removed using etching such as grinding or plasma etching, but the present disclosure is not limited thereto, and a portion of the first insulating layer 111 may be removed through another known method such as polishing or the like.

The operation of forming the first wiring layer 121 may be performed by forming an wiring layer on each of the lower surface of the glass layer 110 and the lower surface of the first insulating layer 111. The lower surface of the first insulating layer 111 may be a flat surface, and the lower surface of the glass layer 110 may also be a flat surface substantially coplanar with the lower surface of the first insulating layer 111, such that the first wiring layer 121 may be formed. In this case, a portion of the first wiring layer 121, formed on the lower surface of the glass layer 110, may be formed to be in contact with the through-via 130, and a portion of the first wiring layer 121, formed on the lower surface of the first insulating layer 111, may be formed to be in contact with the metal pillar 203. That is, in the method of manufacturing the printed circuit board according to another example, an operation of forming a first via layer 131 may be omitted, thereby simplifying an operation of forming a via hole in the first insulating layer 111. The first insulating layer 111 may not extend to the lower surface of the glass layer 110, thereby further reducing a thickness of the printed circuit board.

Referring to FIG. 7D, the method may include an operation of forming a second insulating layer 112, a second wiring layer 122, and a second via layer 132 on the lower surface of the glass layer 110 and the lower surface of the first insulating layer 111, and an operation of forming a solder resist layer 140. The first insulating layer 111 may not extend to the lower surface of the glass layer 110, such that a portion of the second insulating layer 112 may be in contact with the lower surface of the glass layer 110, and another portion of the second insulating layer 112 may be in contact with the first insulating layer 111. A description of the method of manufacturing the printed circuit board according to an example may be applied to the operation of forming the second insulating layer 112, the second wiring layer 122, and the second via layer 132 in the same manner, and thus repeated descriptions will be omitted.

Operations of the method of manufacturing the printed circuit board according to another example, excluding the above-described operations, may be the same as the operations of the method of manufacturing the printed circuit board according to an example, and thus repeated descriptions related thereto will be omitted.

As used herein, the terms “cover,” “to cover,” and “covering” may include entirely covering as well as at least partially covering, and may include directly covering as well as indirectly covering. In addition, the terms “fill,” to fill, “and “filling” may include not only completely filling, but also approximately filling, for example, may include a case in which some voids, pores or the like are present.

As used herein, a process error or a positional deviation occurring in a manufacturing process, an error in measurement, and the like may be included. For example, “substantially perpendicular” may include not only “completely perpendicular,” but also “approximately perpendicular.” In addition, “substantially coplanar” may include not only “completely coplanar,” but also “approximately coplanar.”

As used herein, the same insulating material may mean not only the exact same insulating material, but also the same type of insulating material. Thus, compositions of insulating materials may be substantially the same, but specific composition ratios thereof may slightly vary.

As used herein, a cross-sectional shape may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper” and “lower” may change at any time.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, the term “an example embodiment” is provided to emphasize a particular feature, structure, or characteristic, and do not necessarily refer to the same example embodiment. In addition, the particular characteristics or features may be combined in any suitable manner in one or more example embodiments. For example, a context described in a specific example embodiment may be used in other example embodiments, even if it is not described in the other example embodiments, unless it is described contrary to or inconsistent with the context in the other example embodiments.

The terms used herein describe particular example embodiments only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a glass layer having a cavity;
a through-via having a through-portion penetrating the glass layer, and a protrusion portion protruding upwards from an upper surface of the glass layer;
an electronic component disposed in the cavity; and
a first insulating layer filling at least a portion of the cavity, the first insulating layer covering at least a portion of the electronic component.

2. The printed circuit board of claim 1, wherein the through-portion and the protrusion portion are integrally formed.

3. The printed circuit board of claim 1, wherein the first insulating layer is disposed to extend onto a lower surface of the glass layer.

4. The printed circuit board of claim 3, further comprising:
a first wiring layer disposed on the first insulating layer; and
a first via layer having at least a portion in contact with the through-via, the first via layer penetrating at least a portion of the first insulating layer to connect the first wiring layer and the through-via to each other.

5. The printed circuit board of claim 4, further comprising:
a second insulating layer disposed on the first insulating layer;
a second wiring layer disposed on the second insulating layer; and
a second via layer penetrating at least a portion of the second insulating layer to connect the second wiring layer and the first wiring layer to each other or to connect the second wiring layers to each other.

6. The printed circuit board of claim 1, wherein
the electronic component includes a metal pillar, and
the metal pillar protrudes toward an upper side of the first insulating layer.

7. The printed circuit board of claim 6, wherein an upper surface of the metal pillar is substantially coplanar with an upper surface of the through-portion of the through-via.

8. The printed circuit board of claim 7, wherein the metal pillar is disposed on each of an upper side and a lower side of the electronic component.

9. The printed circuit board of claim 1, wherein a lower surface of the through-via is substantially coplanar with a lower surface of the glass layer.

10. The printed circuit board of claim 1, wherein an upper surface of the first insulating layer is substantially coplanar with the upper surface of the glass layer.

11. The printed circuit board of claim 1, wherein a lower surface of the first insulating layer is substantially coplanar with a lower surface of the glass layer.

12. The printed circuit board of claim 11, further comprising:
a first wiring layer having at least a portion disposed on the lower surface of the glass layer,
wherein at least a portion of the first wiring layer is in contact with the through-via.

13. A printed circuit board comprising:
a glass layer; and
a through-via having a through-portion penetrating the glass layer, and a protrusion portion protruding upwards from an upper surface of the glass layer,
wherein, in cross-section, a width of an uppermost side of the through-portion is substantially equal to a width of a lowermost side of the protrusion portion.

14. The printed circuit board of claim 13, wherein the through-portion and the protrusion portion are integrally formed.

15. The printed circuit board of claim 13, wherein
a lower surface of the through-portion is substantially coplanar with a lower surface of the glass layer.

16. The printed circuit board of claim 13, wherein the through-via has a substantially upwardly tapered shape.

17. The printed circuit board of claim 13, further comprising:
a cavity penetrating at least a portion of the glass layer,
wherein the cavity and the through-via have a tapered shape in the substantially same direction.

18. The printed circuit board of claim 17, further comprising an electronic component disposed in the cavity.

19. The printed circuit board of claim 18, wherein the electronic component comprises a metal pillar extending from of a surface of the electronic component at least up to a plane coplanar with one or both of the upper surface and a lower surface of the glass layer.

20. A printed circuit board, comprising:
a glass layer having through-holes penetrating through the glass layer from an upper surface to a lower surface thereof, at least one of the through-holes being filled with a metal to form a through-via, the through-via having a protrusion portion extending past the upper surface of the glass layer to form a protrusion; and
an electronic component disposed in at least one of the through-holes not filled with the metal.

21. The printed circuit board of claim 20, wherein a lower surface of the through-via is coplanar with the lower surface of the glass layer.

22. The printed circuit board of claim 20, wherein the electronic component comprises a metal pillar extending from of a surface of the electronic component at least up to a plane coplanar with one or both of the upper surface and the lower surface of the glass layer.

23. The printed circuit board of claim 22, further comprising a semiconductor chip connected to the electronic component via the metal pillar.

24. The printed circuit board of claim 23, wherein at the protrusion portion of the through-via is connected to the semiconductor chip.

25. The printed circuit board of claim 20, further comprising a first insulating layer filling at least a portion of the through-hole in which the electronic component is disposed so as to encapsulate at leas a portion of the electronic component.

26. The printed circuit board of claim 25, wherein the first insulating layer has exposed surfaces substantially coplanar with one or both of the upper and lower surfaces of the glass layer.
